(19) United States
(12) Patent Application Publication
(10) Pub. No.: US 2026/0038557 A1
(43) Pub. Date: Feb. 5, 2026

(54) APPARATUSES AND METHODS FOR MEMORY ARRAY WITH ACTIVATE BASED COUNT ACCESS COUNT UPDATE AND BACKGROUND REFRESH

(71) Applicant: Micron Technology, Inc., Boise, ID (US)

(72) Inventors: Sujeet Ayyapureddi, Boise, ID (US); Gary Howe, Boise, ID (US)

(73) Assignee: Micron Technology, Inc., Boise, ID (US)

(21) Appl. No.: 19/270,314

(22) Filed: Jul. 15, 2025

Related U.S. Application Data
(60) Provisional application No. 63/677,088, filed on Jul. 30, 2024.

(51) Int. Cl. G11C 11/406; G11C 11/408

(52) U.S. Cl. CPC G11C 11/406; G11C 11/4087

(57) ABSTRACT

A memory has a bank with at least two row decoders each of which control at least two portions of the bank. Each word line has an associated access count which is stored along a word line coupled to a different row decoder. For example, if the memory receives an activate command and a row address that specifies a first word line associated with the first row decoder, then a second word line in a second portion associated with the second row decoder is also activated and an access count along the second word line is read out and updated. When an access is performed, the memory determines if a background refresh may be performed in a third portion also associated with the second row decoder.

### CROSS REFERENCE TO RELATED APPLICATION(S)

This application claims the benefit under 35 U.S.C. § 119 of the earlier filing date of U.S. Provisional Application Ser. No. 63/677,088 filed Jul. 30, 2024 the entire contents of which is hereby incorporated by reference in its entirety for any purpose.

### BACKGROUND

Information may be stored on memory cells of a memory device. The memory cells may be organized at the intersection of word lines (rows) and bit lines (columns). Information in the memory cells may decay over time. For example, the information may be stored as a charge on a capacitor which may decay over time. The memory device may perform refresh operations to restore the information and prevent information from being lost.

Certain patterns of access may cause an increased rate of information decay in nearby memory cells (e.g., the memory cells along nearby word lines). Memory devices may use various schemes to identify these access patterns so that additional targeted refresh operations may be performed. Memory devices may track accesses to different word lines in order to determine when targeted refresh operations are called for and where they should be performed. There may be a need to optimize the timing of adjusting the access counts. It may also be useful to optimize the timing at which refresh operations are performed.

### BRIEF DESCRIPTION OF THE DRAWINGS

FIG. 1 is a block diagram of a semiconductor device according to at least one embodiment of the disclosure.

FIG. 2 is a block diagram of bank logic circuits according to some examples of the present disclosure.

FIG. 3 is a schematic diagram of an example layout of a memory bank according to some embodiments of the present disclosure.

FIG. 4 is a timing diagram of a memory operation according to some embodiments of the present disclosure.

FIG. 5 is a flow chart of a method of operating a memory device according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated based on a row address. Selected memory cells along that active word line may have their information read from or written to based on which bit lines are selected by a column address. The word line is deactivated when it is pre-charged. The memory may have different timing specifications. For example, a time tRAS is the minimum time after an activation command before a pre-charge command can be received. A time tRCD specifies the minimum time after an activation command before a column command, such as a read or write, may be received. A time tRP is a minimum time after a pre-charge command before a next activation command can be received. Together these give a minimum activate to activate timing tRC.

Information in the memory cells decays over time. To prevent information loss, the memory array may be refreshed on a row-by-row basis (e.g., as part of an auto-refresh and/or self-refresh mode) where the memory cells along each row are refreshed periodically to restore the stored information to an initial value. Such refresh operations may be referred to as sequential refresh operations or normal refresh operations, as the memory may use some sequence logic (e.g., a counter) to generate refresh addresses used to determine which word lines are refreshed. The speed at which the rows are refreshed (e.g., the maximum time any given row will go between refreshes) may be determined based on an expected rate of information decay and may be adjusted based on various conditions of the memory (e.g., temperature).

Various patterns of access to a row (an aggressor row) may cause an increased rate of information decay in nearby memory cells (e.g., along victim rows). For example, a ‘row hammer’ may involve repeated accesses to the aggressor row which may increase a rate of decay in adjacent rows (and/or in rows which are further away). Accordingly, it may be important to track a number of accesses to each row to determine if they are aggressors, such that the victim rows can be identified and refreshed as part of a targeted refresh operation. For example, per-row access counts (PRAC) may be used where each word line may have an associated access count value which is used to determine how many times that word line has been accessed. The access counts may be used to determine if the row is an aggressor, for example if the access count crosses a threshold.

When a word line is accessed, an access count update (ACU) operation is performed where the access count associated with that word line is read out, modified (e.g., incremented), and then the updated access count is written back. This may affect the timing of operations, since a read-modify-write (RMW) is performed on the access count. In a conventional memory device the access counts may share a read path with the word line being accessed. Accordingly, the ACU operation may be performed when the pre-charge command is received, indicating that no more column commands are being performed on that word line, so that the ACU operation doesn't interfere. This may lead to a shortened tRAS timing and an increased tRP timing. However, the shortened tRAS timing may prevent column commands from being performed without causing extensions of tRP. Since this decreases the performance of the memory, it may be useful to find ways to perform ACU operations while allowing a tRAS duration that allows for column commands without an extended timing. Similarly, when a refresh operation is performed, they may take up time which could have otherwise been used for access operations of the memory. This may be inefficient, as the memory may need to perform refresh operations relatively frequently. It may be useful for the memory to be able to perform both refresh operations and ACU operations during normal access operations.

The present disclosure is drawn to apparatuses, systems, and methods for a memory array with activate based access count update and background refresh. The memory banks of the array are divided into quadrants. Each quadrant is coupled to a respective column decoder. A first half of the bank including two of the quadrants is coupled to a first row decoder and a second half of the bank including the other two of the quadrants is coupled to a second decoder. When an access operation is performed, if the access operation is performed in the first half of the array, then the ACU operation is performed in the second half of the array and there is also an opportunity for a background refresh operation to be performed in the second half of the array. The ACU operation is performed in one quadrant of the second half and the refresh may be performed in the other quadrant of the second half. In this manner, different row decoders are used for the access and the access count update/background refresh, and different column decoders are used for the access count update and background refresh (which share a row decoder). This may allow for an access, an ACU, and a refresh to all happen during tRAS timing of the access operation. This may allow tRAS to be longer than tRP. Since tRAS is extended, one or more column commands may be performed during tRAS without causing an extension of the overall tRC timing.

In an example implementation, the memory device may receive a row activation command at a first time and a row address as part of an access operation. The memory device determines identifies a quadrant of the memory bank where there is a background refresh opportunity based on the quadrant specified by the row address. The memory uses internal logic to determine whether or not to perform a background refresh or not in that quadrant. Responsive to the row activation command and the row address, a first row decoder activates a first word line in a first half of the bank and a second row decoder activates a second word line in a second half of the bank. If a background refresh operation is being performed, the second row decoder also activates a third word line in the second half of the bank. The second and third word lines are in different quadrants of the second half. An operation control circuit uses the row address to determine which quadrant of the bank the row address is associated with. The operation control circuit provides signals to the column decoders and refresh circuits so that they perform the appropriate operations with the correct timings. For example, a first column decoder may be used to perform column commands (e.g., read or write) on the first word line. A second column decoder and a refresh circuit may perform the ACU operation on a count value stored along the second word line. That count value is associated with the first word line. A third column decoder resets the PRAC count along a third word line when it is refreshed. At a second time after the first time, a pre-charge command is received. Responsive to this, the first row decoder pre-charges the first word line and the second row decoder pre-charges the second word line and the third word line.

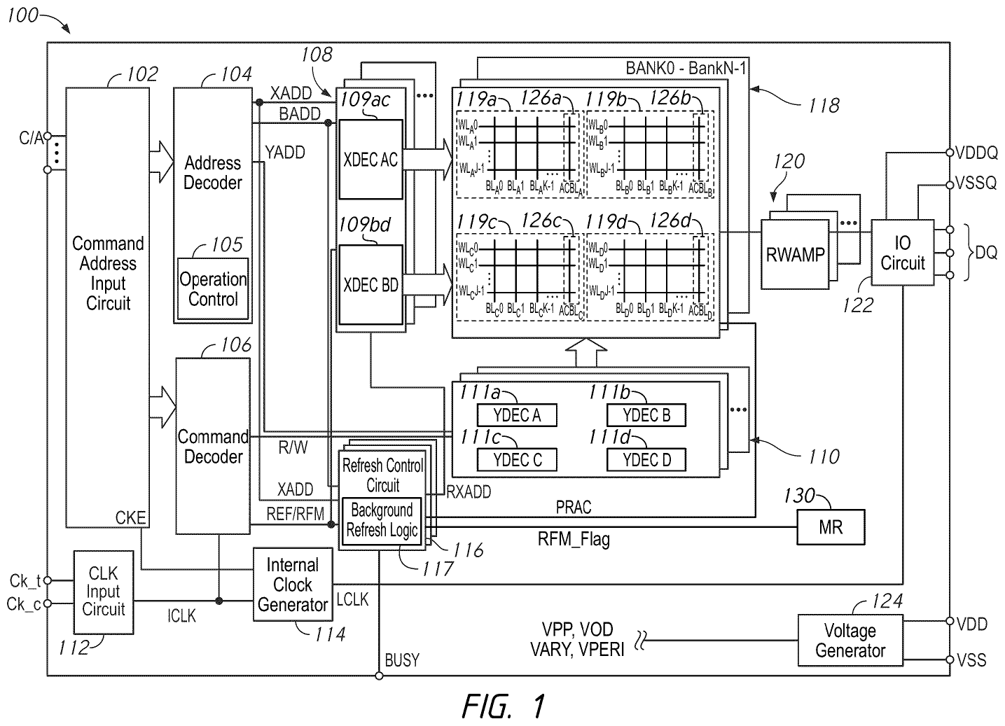

FIG. 1 is a block diagram of a semiconductor device according to at least one embodiment of the disclosure. The semiconductor device 100 may be a semiconductor memory device, such as a DRAM device integrated on a single semiconductor chip. The device 100 may be operated by a host or controller (not shown). The controller may be any device (or collection of devices) which stores information on the memory. For example, the controller may be a processor. In some embodiments, the controller and memory 100 may be packaged together on a single integrated circuit. In some embodiments, the controller and memory 100 may be separate. In some embodiments, the controller may operate multiple memory devices 100.

The semiconductor device 100 includes a memory array 118. The memory array 118 may organized into one or more memory banks. In the embodiment of FIG. 1, the memory array 118 is shown as including N memory banks BANK0-BANKN−1. For example there may be 2, 4, 8, or 16 memory banks. More or fewer banks may be included in the memory array 218 of other embodiments. Each memory bank includes a plurality of word lines WL (rows), a plurality of bit lines BL (columns), and a plurality of memory cells arranged at intersections of the plurality of word lines WL and the plurality of bit lines BL. Each bank is associated with a value of a bank address BADD.

The selection of the word line WL is performed by bank row decoders 108 and the selection of the bit lines BL is performed by a column decoder 110. Certain circuits, such as the bank row decoders 108 and the column decoder 110 are repeated on a bank-by-bank basis. For example, if there are N banks there may be N bank row decoders 108 and N column decoders 110. Certain other circuits of the memory device 100 may also be repeated on a bank-by-bank basis. For example, each bank may have an associated bank logic region which includes the circuits associated with that bank.

The bit lines BL are coupled to a respective sense amplifier (SAMP). The sense amplifiers are coupled to local input/output (LIO) and global input/output (GIO) to read/write amplifiers (RWAMP) 120 and through those to the input/output circuits 122 of the memory device 100. During an access operation, the bank row decoder circuits 108 activate a word line specified by the row address responsive to an activate command. The activated word line couples the memory cells along that word line to the intersecting bit lines. During a read operation, the sense amplifiers amplify the signal along that bit line to a voltage that represents the logical level stored in the memory cell. During a write operation, the sense amplifiers receive a signal indicating a logical level to be written and amplify it onto the bit line and through the bit line to the memory cell. During a refresh operation, the sense amplifiers amplify the value on the bit line back to an initial value and restore that value to the memory cell. The column decoder 110 may selects which bit lines are coupled in and out of the memory bank 118 based on a column address and what type of operation is performed based on a decoded command. After operations, the bank row decoder circuits 108 pre-charge the word line responsive to a pre-charge command.

The banks may be divided into one or more portions 119, each of which include their own respective portion of the memory cells, word lines, bit lines, and sense amplifiers in the bank. As described in more detail herein, the bank may be divided into four portions 119, and the portions 119 may also be referred to as ‘quadrants’. While the term quadrants may generally be used herein, other numbers of portions 119 may be used in other example embodiments. For example, if more than four portions are used, then three of the portions may be used for access, refresh, and ACU, while the remainder may go unused for a given operation.

In the example of FIG. 1, the bank 118 is divided into four quadrants, 119a, 119b, 119c, and 119d, each with their own respective set of word lines WL_{A}, WL_{B}, WL_{C}, and WL_{D}, and their own respective set of bit lines BL_{A}, BL_{B}, BL_{C}, and BL_{D}. Each quadrant 119a-d also has memory cells at the intersection of their word lines WL and bit lines, and sense amplifiers (not shown) coupled to the bit lines. The different portions 119a-d may have a same or different number of word lines, bit lines, or combinations thereof. The bank row decoder circuits 108 for that bank include two row decoders 109ac and 109bd. The row decoder 109ac is associated with the first portion 119a and the third portion 119c. The second row decoder 109bd is associated with the second portion 119b and the fourth portion 119d. One or more bits of the row address XADD may specify which portion 119a-d to perform the access operation in.

The bank level column decoder 110 includes four column decoders 111a, 111b, 111c, and 111d, each associated with a respective one of the four portions 119a-d of the bank 118. For example, the first column decoder 111a is associated with the first portion 119a, the second column decoder 111b is associated with the second portion 119b, the third column decoder 111c is associated with the third portion 119c and the fourth column decoder 111d is associated with the fourth portion 119d. An operation control circuit 105 determines which column decoder circuits 111a-d activate and what operations are performed based on the row address.

The semiconductor device 100 may employ a plurality of external terminals coupled to the controller. The external terminals include command and address (C/A) terminals coupled to the controller along a command and address bus to receive commands and addresses. Other external terminals include clock terminals to receive clocks clock signals CK and/CK along a clock bus, data terminals DQ to send and receive data along a data bus, and power supply terminals to receive power supply potentials such as VDD, VSS, VDDQ, and VSSQ.

The clock terminals are supplied by the controller with external clocks CK and/CK that are provided to an input circuit 112. The external clocks may be complementary. The input circuit 112 generates an internal clock ICLK based on the CK and/CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses by the controller. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include access commands such as a row activation command ACT, one or more column commands such as read or write, and pre-charge command PRE, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. The command decoder 104 includes an operation control circuit 105 which is used to perform multiple operations on one or more of the quadrants 119a-d of the bank 118. For example, based on the row address XADD associated with a row activation command, the operation control circuit 105 may instruct one of the column decoders 111a-d to perform an access operation, another to perform an ACU operation, and instruct the refresh control circuit 116 to determine if a background refresh operation is performed by a third column decoder. The background refresh decision may be made at row activation time.

As part of an example write operation, the C/A terminals receive a row activation command ACT and a row address. The row address includes one or more bits which specify which portion 109a-d to activate. The selected row decoder 109ac or 109bd activates the specified word line. As explained in more detail herein, the non-selected row decoder 109bd or 109ac activates an associated word line in the non-selected portion and the column decoder 111 associated with that portion performs an ACU operation on a count value in the non-selected portion responsive to the ACT command. The refresh control circuit checks if a background refresh operation should be performed in the quadrant that uses the row decoder not selected by the row address, but not used for the ACU operation. If a background refresh operation is called for, the non-selected row decoder 109bd activates another word line and perform a refresh operation. The C/A terminals receive a column command, in this case write, along with a column address. The column decoder couples bit lines specified by the column address YADD to the LIO and GIO lines. The input/output circuit receives data along the data terminals DQ. The data is provided through the RWAMP 120 through the LIO and GIO lines to the specified bit lines. When the controller is done performing operations on the word line, the memory device 100 receives a pre-charge command PRE, and the active word lines are pre-charged.

As part of an example read operation, the C/A terminals receive a row activation command ACT and a row address. The row address includes one or more bits which specify which portion 109a-d to activate. The selected row decoder 109ac or 109bd activates the specified word line. As explained in more detail herein, the non-selected row decoder 109bd or 109ac activates an associated word line in the non-selected portion and the column decoder 111 associated with that portion performs an ACU operation on a count value in the non-selected portion responsive to the ACT command. The refresh control circuit checks if a background refresh operation should be performed in the quadrant that uses the row decoder not selected by the row address, but not used for the ACU operation. If a background refresh operation is called for, the non-selected row decoder 109bd activates another word line and perform a refresh operation. The C/A terminals receive a column command, in this case read, along with a column address. The column decoder couples bit lines specified by the column address YADD to the LIO and GIO lines. The sense amplifiers amplify the signal from the intersecting memory cells along the bit lines to the LIO and GIO lines through the RWAMP 120 to the IO circuit 122. The IO circuit 122 provides the read data to the data terminals DQ. When the controller is done performing operations on the word line, the memory device 100 receives a pre-charge command PRE, and the active word lines are pre-charged.

The device includes a refresh control circuit 116 which is used to perform refresh operations. As part of a refresh operation, the refresh control circuit 116 issues a refresh address RXADD, and the bank row decoder circuits 108 and bank column decoder circuits 110 may refresh one or more word lines based on the refresh address RXADD. In some embodiments, the refresh control circuit 116 may be repeated on a bank-by-bank basis, similar to the row decoder 108 and column decoder 110.

The device 100 may perform ‘hidden’ or ‘background’ refresh operations by performing a refresh operation responsive to a row activation command. The refresh control circuit 116 includes one or more background refresh logic circuits 117 which receive one or more signals which indicate which portion 119a-d is being accessed. Based on that, the background refresh logic 117 determines which portion 119a-d has an opportunity for a background refresh. The background refresh logic 117 determines whether or not to perform a background refresh in that quadrant. For example, responsive to a row activation command and row address XADD which specifies one of the row decoders 109ac or 109bd, the background refresh logic may determine which one of the portions coupled to the non-selected decoder has the opportunity for a background refresh. For example, the background refresh logic 117 may compare a refresh count associated with that portion to an expected number of refreshes, and if there is a deficit determine to perform a background refresh.

In some embodiments, the device 100 may also receive commands causing it to carry out refresh operations. For example, the controller may issue a refresh command REF or a refresh management command RFM. Responsive to either the REF command or the RFM command, the refresh control circuit 116 may perform one or more refresh operations. The refresh operations performed responsive to a specific refresh command (e.g., REF or RFM) may generally be referred to as ‘stand-alone’ refresh operations (since they are not performed along with an access) while the refresh operations performed responsive to a row activation command may be referred to as ‘background’ or ‘hidden’ refreshes, since the memory device 100 performs those in the background while performing another task that the controller has requested (e.g., an access operation).

As part of a refresh operation, either stand-alone or background, the refresh address control circuit 116 supplies one or more refresh addresses RXADD to the row decoders 108, which refreshes one or more wordlines WL identified by the refresh row address RXADD. Different refresh operations may cause the refresh address RXADD to be generated in different ways. For example, in some embodiments, the refresh control circuit 116 may perform, normal (or sequential) refresh operations responsive to a row activation command, a mix of normal (or sequential) refresh operations and targeted refresh operations responsive to the refresh command REF, and may perform targeted refresh operations responsive to the RFM command. In some embodiments, the refresh control circuit 116 may perform normal refresh operations responsive to REF and targeted refresh commands responsive to RFM.

The refresh control circuit 116 may perform a sequential refresh operation, or normal refresh operation, by issuing one or more sequential refresh addresses as RXADD. The sequential refresh addresses may be generated based on a sequence of addresses. For example, after issuing a sequential refresh address, a counter circuit may increment the address to generate the next address in the sequence (e.g., RXADD(i)=RXADD(i−1)+1). In some embodiments, there may be a counter circuit for each portion 119a-d of the bank 118. In some embodiments, the sequence of sequential addresses may include all the addresses in the memory bank 118.

The refresh control circuit 116 may perform a targeted refresh operation, for example responsive to an RFM command. The refresh control circuit 116 identifies addresses as targets for targeted refresh operations. These addresses may generally be referred to as aggressors, although different embodiments may use different criteria for identifying these addresses. The refresh control circuit 116 may include a register which stores identified aggressors. As part of a targeted refresh operation, one or more refresh addresses are generated based on a selected aggressor. For example, in some embodiments, the refresh addresses may represent word lines which are physically adjacent to the word line associated with the identified aggressor address (e.g., RXADD=XADD+/−1). Other relationships may be used in other example embodiments. For example word lines which are further away (e.g., RXADD=XADD+/−2, +/−3, etc.) may be refreshed.

The memory device 100 uses per row activity counts (PRAC) to determine which rows are aggressors. In the example embodiment of FIG. 1, some of the memory cells of the array 118 may be set aside to store access counts. The memory cells 126a-d which are set aside for such a purpose may generally be referred to as counter memory cells 126a-d. The counter memory cells 126a-d may store access count values PRAC, each of which is associated with one of the word lines. The count value PRAC may be stored as a binary number, with each bit stored in a memory cell along the word line. The counter memory cells are stored in memory cells along access count bit lines ACBL. The number of counter memory cells along each word line may be based on a number of bits of the count value PRAC. Each portion 119a-d includes a respective set of counter memory cells 126a-d. The counter memory cells 126a-d store count values associated with a word line in a different one of the portions. For example, the count values 126a may be associated with the word lines in portion 119b, the count values 126b may be associated with the word lines in portion 119a, the count values 126c may be associated with the word lines in portion 119d, and the count values 126d may be associated with the word lines in portion 119c.

In some embodiments, the counter memory cells 126a-d and access count bit lines may be referred to as such due to their use (storing the count values) and in some embodiments may be structurally similar to, or identical to, the other memory cells and bit lines of the array. In some embodiments, the counter memory cells 126a-d may be grouped together (e.g., at the end of the word line). Other distributions of the counter memory cells 126 along the word line may be used in other example embodiments. In some embodiments, the counter memory cells 126a-d may not be directly accessible by external devices such as controllers (e.g., to prevent the count values from being overwritten). In other words, the access count bit lines ACBL associated with the counter memory cells 126a-d may not be accessed by a normal column address.

The count values PRAC may be used to determine if the associated word line is an aggressor or not. For example, each time a word line is activated, a count value PRAC associated with that word line is updated as part of an ACU operation. As part of an ACU operation, the count value PRAC associated with the row specified by XADD is read out to the refresh control circuit 116 and the refresh control circuit 116 updates the count, compares the updated count to a threshold and writes the updated count back to the counter memory cells 126. For example the count may be updated by being incremented as part of the ACU operation. If the updated count crosses the threshold, then the row address XADD may be stored as an aggressor and the count value may be updated by being reset to an initial value (e.g., 0). In some embodiments, the threshold may represent a maximum value of the count and the count may cross the threshold by ‘rolling over’ back to the initial value (e.g., from 11111111 to 00000000).

The count values for each word line are stored in a different portion of the bank than the portion which includes the word line. In particular, the count values for the word lines in the portions 119a and 119c coupled to the first row decoder 109ac are stored in portions 119b and 119d coupled to the second row decoder 109bd. For example, the PRAC counts for the word lines of the first portion 119a are stored along word lines in the second portion 119b and vice versa, and the PRAC counts for the word lines of the third portion 119c are stored in the fourth portion 119d and vice versa. Accordingly, if the row address XADD received along with an activate command ACT specifies the first portion 119a, both row decoders 109ac and 109bd will activate word lines, and an ACU operation will be performed on the PRAC stored along the word line in the second portion 119b. Similarly, the second row decoder 109bd will also activate one or more word lines in the other coupled portion, 119d in this case, and a normal refresh operation will be performed on the one or more word lines of that portion.

The power supply terminals are supplied with power supply potentials VDD and VSS. The power supply potentials VDD and VSS are supplied to an internal voltage generator circuit 124. The internal voltage generator circuit 224 generates various internal potentials VPP, VARY, VPERI, and the like based on the power supply potentials VDD and VSS supplied to the power supply terminals. The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

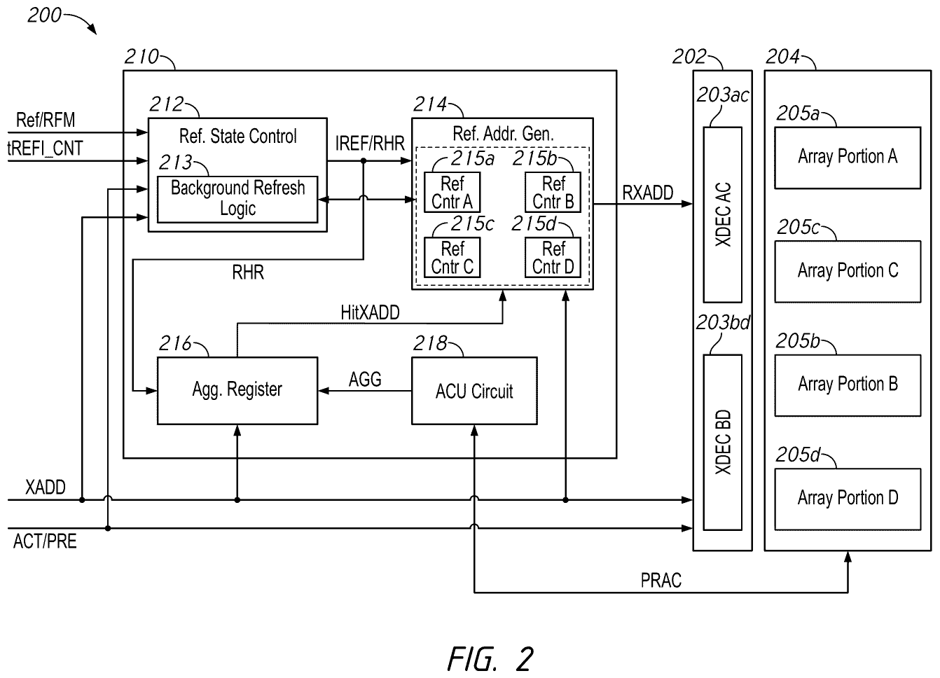

FIG. 2 is a block diagram of bank logic circuits according to some examples of the present disclosure. The bank logic circuits 200 may, in some embodiments, implement a part of a memory device such as 100 of FIG. 1. For example, the bank logic circuits 200 may represent selected circuits in a bank logic region associated with a bank of the memory array. The bank logic circuits 200 of FIG. 2 shows a refresh control circuit 210 (e.g., 116 of FIG. 1), a row decoder 202 (e.g., 108 of FIG. 1) and a memory bank 204 (e.g., 118 of FIG. 1). Certain other circuits which may be part of the bank logic, such as the column decoder, are omitted from the view of FIG. 2.

The refresh control circuit 210 includes a refresh state control circuit 212, a refresh address generator 214, an aggressor register 216 and an ACU logic circuit 218. The refresh state control circuit 212 determines how many refresh operations should be performed and what types. The refresh address generator circuit 214 generates the refresh address RXADD. The aggressor register 216 stores one or more identified aggressor addresses HitXADD. The ACU logic circuit 218 updates the PRAC count when a word line is accessed and uses the PRAC to determine if the word line is an aggressor. The memory bank 204 is split into a first portion 205a (e.g., 119a of FIG. 1) and a third portion 205c (e.g., 119c of FIG. 1) both associated with a first row decoder 203ac (e.g., 109ac of FIG. 1) and a second portion 205b (e.g., 119b of FIG. 1) and fourth portion 205d (e.g., 119d) both associated with a second row decoder 205bd (e.g., 109bd of FIG. 1).

The refresh control circuit 212 determines how many refresh operations to perform and of what type(s). For example, the refresh state control circuit 212 provides an internal refresh signal IREF to indicate a normal refresh operation and a targeted refresh signal RHR to indicate a targeted refresh operation. Other signals may be used in other example embodiments.

The refresh control circuit 212 may perform a background or hidden refresh operation while the row is being accessed. The refresh state control circuit 212 includes a background refresh logic circuit 213 (e.g., 117 of FIG. 1) which is used to determine where in the bank 204 there is a background refresh opportunity and if a background refresh operation should be performed. In some embodiments, if a background refresh is performed, the background refresh operation may be a normal refresh operation. For example, responsive to the activation signal ACT, if the background refresh logic 213 determines that a background refresh operation should be performed, the refresh state control circuit 212 may generate an internal refresh signal IREF. In some embodiments the background refresh logic 212 may determine which portion 205a-d has a background refresh opportunity based on the row address XADD, then compare a value of a refresh counter 215a-d associated with that portion to a refresh interval count tREFI_CNT, which represents the expected number of refresh operations. If there is a deficit, such as the refresh counter 215a-d being behind the expected number of refreshes, then the background refresh logic 213 may determine that a background refresh operation should be performed in that portion.

In some embodiments, the refresh control circuit 212 may additionally perform stand-alone refresh operations responsive to refresh commands such as REF and/or RFM. In some example implementations, responsive to the refresh signal REF, the refresh state control circuit 212 may perform multiple refresh operations for each time REF or RFM is received. For example, two, four, six, more or fewer refresh operations may be performed. In some example implementations, the refresh state control circuit 212 may perform only normal refresh operations responsive to REF and perform targeted refresh operations responsive to RFM. In some example implementations the refresh state control circuit 212 may perform a mix of normal and targeted refresh operations responsive to REF and perform targeted refresh operations responsive to RFM.

The refresh address generator 214 generates a refresh address RXADD responsive to IREF, RHR, or combinations thereof. For example, responsive to IREF, indicating a normal refresh address, the refresh address generator circuit 214 generates the refresh address RXADD based on sequence logic. For example, the refresh address generator circuit 214 may include refresh address counters 215a-d, which increments a value to generate a refresh address for normal refresh operations. Each portion 205a-d of the array has an associated refresh address counter 215a-d. The counters 215a-d may have independent values from each other. Each counter 215a-d is used to count the progress of normal refresh operations through the associated portion 205a-d.

Responsive to a targeted refresh operation (e.g., the signal RHR) the refresh address generator 214 uses an aggressor address HitXADD to generate one or more refresh addresses. For example, the refresh addresses may represent the word lines which are adjacent to the word line associated with HitXADD. In some embodiments, during a normal refresh operation multiple word lines may be refreshed, while during a targeted refresh operation a single word line may be refreshed. For example, the refresh address generated for a normal refresh operation may be truncated, and every word line which has an address which shares that truncated portion in common may be refreshed by the row decoder 202.

When a word line is accessed, its associated PRAC count is read out to the ACU logic circuit 218. The row address XADD may indicate if it is associated with the first row decoder 203ac or the second row decoder 203bd. For example, a decoder select bit of the row address may have a first state if the row address specifies the first portion 205a or the third portion 205c or a second state if the row address specifies the second portion 205b or the fourth portion 205d. In an example implementation, the bank 204 may be organized such that all of the row addresses which have a most significant bit (MSB) at a logical high are in the first portion 205a or the third portion 205c and all of the row addresses which have a MSB at a logical low are in the second portion 205b or the fourth portion 205d. Accordingly, the most significant bit may act as the decoder select bit.

In some example implementations, the decoder select bit (e.g., the MSB) of the row address may specify a row decoder 203ac or 203bd, and a remaining value of the row address may specify the portion 205a/205b or 205c/205d. For example, if there are P total rows associated with each row decoder 203, then the portions 205a/205c include rows with the indices 0 to P/2-1 and the portions 205b/205d include rows with the indices P/2 to P−1. Thus, if the row address decodes to a value between 0 to P/2-1 and has a decoder select bit in the first state, then it may indicate a word line in the first portion 205a, if the row address decodes to a value between 0 to P/2-1 and has a decoder select bit in the second state then it may indicate a word line in the second portion 205b, if the row address decodes to a value between P/2 to P−1 and has a decoder select bit in the first state then it may indicate a word line in the third portion 205c, and if the row address decodes to a value between P/2 to P−1 and has a decoder select bit in the second state then it may indicate a word line in the third portion 205d. Other ways of using the row decoder to indicate one of the portions 205a-d may be used in other example embodiments.

Responsive to an activation command ACT, the row decoder 203 selected by the portion select bit of the row address activates a word line in a selected one of the respective portions 205 for the access operation. The row decoder 203 not selected by the portion select bit also activates a word line to read out the PRAC. In an example implementation, the count value may be stored along the word line in the opposite portion which matches the address, but has the portion select bit in the opposite state. For example, when the row address selects a word line in the first portion 205a, the associated count value PRAC is read out from a corresponding word line in the second portion 205b. When the row address selects a word line in the second portion 205b, the associated count value PRAC is read out from a corresponding word line in the first portion 205a. In this manner, word lines may be paired between the two portions 205, and each of the paired word lines may store each other's PRAC value. Other ways of organizing the selected word line in one portion and its associated PRAC in the other portion may be used in other example embodiments.

As part of an ACU operation, the ACU logic circuit 218 receives a PRAC value responsive to an activate command ACT. The ACU logic circuit 218 updates the PRAC value, for example by incrementing the PRAC value. If the PRAC value has not crossed a threshold, the updated PRAC value is written back to its original location in the bank 204. If the PRAC value has crossed a threshold, the ACU logic circuit 218 provides an aggressor signal AGG. In some embodiments, responsive to the PRAC value crossing the threshold, the ACU logic circuit 218 resets the PRAC value, for example to an initial value such as 0.

The aggressor register 216 includes a number of ‘slots’ which may be used to store aggressor addresses. For example, each slot may include a number of latch circuits the length of a row address. Responsive to the aggressor signal AGG, the register 216 adds the current row address XADD to the register. The register 216 may act as a FIFO register in some embodiments.

When an activation command is received, the background refresh logic 213 determines which portion 205a-d has an opportunity for a background refresh. The portion which has a background refresh opportunity is the portion coupled to the row decoder not selected for the access operation, but which does not store the PRAC count associated with the accessed word line. For example, if the row address indicates a word line in portion 205a then there is a background refresh opportunity in portion 205d, if the row address indicates a word line in portion 205c, then there is a background refresh opportunity in portion 205b, if the row address indicates a word line in portion 205b then there is a background refresh opportunity in portion 205c, and if the row address indicates a word line in portion 205d, then there is a background refresh opportunity in portion 205a.

After the background refresh logic 213 determines which portion 205a-d has a background refresh opportunity, it may determine whether or not to use that opportunity and perform a background refresh operation. For example, the background refresh logic 213 may compare the refresh count from the portion which has a background refresh opportunity to an expected number of refreshes. The expected number of refreshes is represented by a refresh interval counter tREFI_CNT. The refresh interval count tREFI_CNT is generated by a refresh interval counter circuit (not shown) which increments with timing based on an average expected rate of refresh operations. For example, the specification of the memory device may require a certain number of refresh operations X over a period of time Y, and thus the refresh interval count tREFI_CNT may update every Y/X amount of time.

The background refresh logic circuit 213 retrieves the refresh count from the refresh counter circuit 215a-d associated with the portion 205a-d where there is a background refresh opportunity and compares the refresh count to tREFI_CNT. If the refresh count is equal to or greater than tREFI_CNT, then there may be no need for a background refresh to be performed in that portion, and no background refresh will be performed. If the refresh count is behind tREFI_CNT, or optionally more than a threshold amount below tREFI_CNT, then a background refresh will be performed. The background refresh logic 212 will send a refresh signal, such as IREF, as well as a signal indicating which portion 205a-d to perform the refresh in. The refresh counter 215a-d associated with the selected portion 205a-d will be used to generate the refresh address RXADD and a background refresh will be performed based on that refresh address.

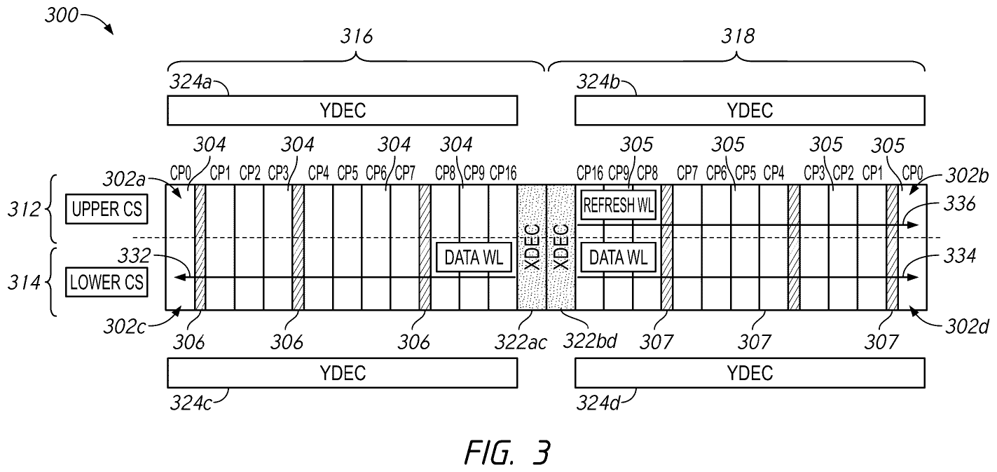

FIG. 3 is a schematic diagram of an example layout of a memory bank according to some embodiments of the present disclosure. The memory bank 300 may, in some embodiments, implement the memory bank 118 of FIG. 1 and/or 204 of FIG. 2. FIG. 3 shows an example layout of the memory bank 300 as well as its associated row decoders 322ac and 322bd (e.g., 109ac/109bd of FIG. 1 and/or 203ac/203bd of FIG. 2) and column decoders 324a-d (e.g., 111a-d of FIG. 1). In describing the layout, terms like ‘up’, ‘down’, ‘left’ and ‘right’ are used to help describe the memory bank 300 with respect to the orientation of the drawing, however it should be understood that these terms are only to aid in understanding relative position, and the memory bank 300 may have any orientation.

The memory bank 300 is divided into quadrants 302a, 302b, 302c, and 302d (e.g., 119a-d of FIG. 1 and/or 205a-d of FIG. 2). The bank 300 is divided into a left half 316 and a right half 318. The memory bank 300 is also divided into an upper half 312 and a lower half 314. Although the terms ‘half’ is used, the portions do not need to be evenly divided in terms of number of word line, bit line, and/or memory cells. The left half 316 includes the portion 302a and 302c and the right half 318 includes the portions 302b and 302d. The upper half 312 includes the portions 302a and 302b and the lower half 314 includes the portions 302c and 302d. The portion 302a may be referred to as being in the upper left, the portion 302b may be referred to as being in the upper right, the portion 302c may be referred to as being in the lower left, and the portion 302d may be referred to as being in the lower right 302d.

The row decoders 322ac and 322bd are positioned between the left half 316 and right half 318. Each row decoder 322ac and 322bd is coupled to word lines extending into the respective half. So the row decoder 322ac is positioned to the right of the memory array in the left half 316 and the row decoder 322bd is positioned to the left of the memory array in the right half 318. The column decoders 324a-d are positioned along the top and bottom of the memory array. The column decoder 324a is positioned above the left half 316 of the array and the column decoder 324c is positioned below the left half 316. The column decoder 324b is positioned above the right half 318 and the column decoder 324d is positioned below the right half 318. The column decoders 324a-d provide column select signals to the bit lines of the bank 300.

The bank 300 is divided into column planes 304 and 305. There are a set of column planes 304 of the left half 316 and a set of column planes 305 on the right half 318. In the example implementation of FIG. 3, there are 17 column planes on each half. In an example use case, sixteen of the column planes on a half may generally be used for data, while the seventeenth on that half is used for error correction bits associated with the data of that half. In addition to the column planes 304 and 305, there are also PRAC column planes 306 and 307 which include the counter memory cells (e.g., 126a-d) used to store the PRAC counts. The PRAC column planes 306 are positioned on the left half 316 and store count values for word lines in the right half 318 and the PRAC column planes 307 are positioned on the right half 318 and store count values for word lines in the left half 316. In the example implementation of FIG. 3, there are 3 PRAC column planes 306/307 on each half, positioned in between the column planes 304/305.

The column planes 304-307 group together multiple bit lines, organized into sets based on a column select value. When the associated column decoder 324 provides a column select value, it selects a set of bit lines in each of the column planes 304 in the portion 302a-d associated with that column decoder. For example, the column decoder 324a may send a column select signal to the bit lines in the upper half 312 of the column planes 304 and 306, while the column decoder 324c may send a column select signal to the bit lines in the lower half 314 of the column planes 304 and 306. Similarly, the column decoder 324b may send a column select signal to the bit lines in the upper half 312 of the column planes 305 and 307, while the column decoder 324d may send a column select signal to the bit lines in the lower half 314 of the column planes 305 and 307. In an example embodiments, responsive to a column select signal, 8 bit lines in each of the column planes are accessed, for a total of 128 data bits, 8 error correction bits, and 24 PRAC bits.

Three example word lines 332 to 336 are shown to help describe an example access operation. The word line 332 is in portion 302c (the lower left), the word line 334 is in portion 302d (the lower right) and the word line 336 is in portion 302b (the upper right). During this example operation, an activate command is received along with a row address which specifies the word line 332. For example the row address may include a select bit which selects the row decoder 322ac, and a value which indicates it is in the lower half 314, thus specifying the portion 302c. Since the word line 332 is in the lower left portion 302c, the word line along which the PRAC count for the word line 332 is stored is in the lower right portion 302d. For example, the word line 334 may have a same value as the row address except that the decoder select bit (e.g., the MSB) is in a different state.

The row address may also indicate a background refresh opportunity in the upper right portion 302b. The portion with the background refresh opportunity is the one which is not selected by the row addresses' decoder select bit and which is not selected by the row addresses' value. In this case, since the row address specifies portion 302c, then the portion 302b is the one which has the background refresh opportunity. In other words, the portion which has the background refresh opportunity is the one which is in the opposite left/right half and the opposite upper/lower half from the portion specified by row address. In contrast the portion which stores the PRAC count is in the opposite left/right half but the same upper/lower half from the portion specified by the row address.

Based on which portion has a background refresh opportunity, the background refresh logic (e.g., 117 of FIG. 1 and/or 213 of FIG. 2) determines whether or not to perform a background refresh. For example, the background refresh logic may determine based on a comparison of the refresh count for the portion with the background refresh opportunity (e.g., 215a-d of FIG. 2) to the expected number of refresh operations. For the sake of this explanation, we will assume that the background refresh logic determines that a background refresh should be performed.

FIG. 3 shows an example operation where an access is performed in the portion 302c, an ACU operation is performed in the portion 302d, and a background refresh is performed in the portion 302b. Based on the row address, the row decoders 322ac and 322bd activate the word lines 332 and 334 respectively. In addition, the refresh control circuit generates a refresh address RXADD in the portion 302b and the row decoder 322bd also activates the word line 336 based on the refresh address RXADD. The column decoder 324c provides a column select signal based on the column address to the column planes 306. This causes data and error correction bits to be accessed in the lower left portion 302c. The column decoder 324d accesses the PRAC column planes 307 of the lower right portion 302d. The PRAC bits from those PRAC column planes 307 are provided to the refresh control circuit for an ACU operation and then written back. In some embodiments, both column decoders 324c and 324d may access both column planes and PRAC column planes, but the column decoder 324c may only perform operations (e.g., read or write) on the column planes 304 while the column decoder 324d may only perform operations (e.g., ACU) on the column planes 307. The column decoder 324b performs a refresh operation on the memory cells along the word line 336. The PRAC value in the portion 302b is reset.

In some embodiments, an operation control circuit (e.g., 105 of FIG. 1) may provide commands to the column decoders 324a-d to instruct them the operation that they should perform. In some embodiments, column decoder 324a may not fire in order to save power, since the portion 302a is unused in this example operation. In some embodiments, some word lines may be positioned in sections of the array which are near the border between the upper half 312 and lower half 314. These word lines may intersect bit lines coupled to both the upper and lower column decoders. Accordingly, if a word line is in one of those sections, both column decoders will fire, even if one is associated with a portion which isn't being used.

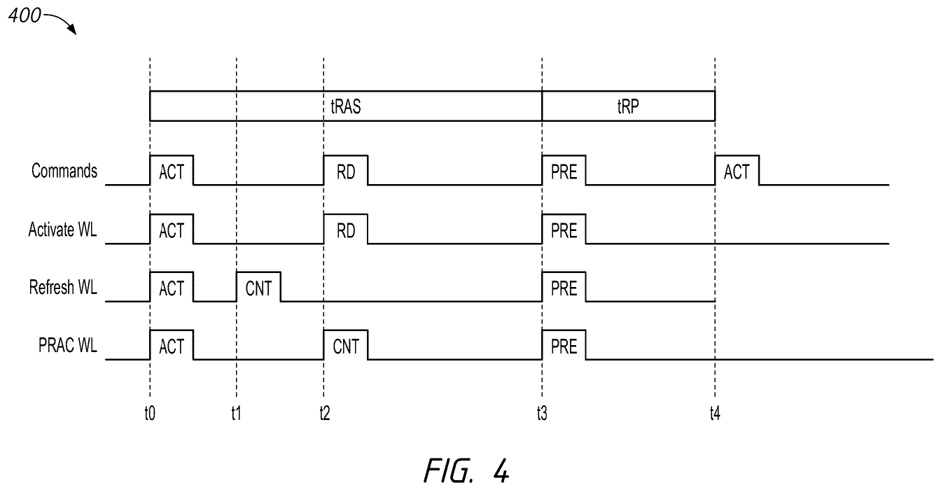

FIG. 4 is a timing diagram of a memory operation according to some embodiments of the present disclosure. The timing diagram 400 may represent the operation of one or more of the apparatuses or systems described herein. For example, the timing diagram 400 may represent the operation of the memory device 100 of FIG. 1, the bank logic circuits 200 of FIG. 2, and/or the bank 300 of FIG. 3. The timing diagram represents the timing of various signals used as part of an access operation along with its associated ACU operation and background refresh.

The timing diagram 400 includes four traces. The first shows commands received by the memory device such as along C/A terminal. The second trace shows internal commands provided row and column decoders to a word line specified by a row address (the ‘Activate WL’) received along with the commands. The third and fourth traces show internal signals provided by row and column decoders to word lines used for a background refresh operation (‘Refresh WL’) and an ACU operation (‘PRAC WL’).

At an initial time t0, the memory device receives an activate command ACT along with a row address (not shown). The row address specifies one of the portions of the memory bank. Based on the row address, a row address for the ACU operation is also specified. For example, the row address for the ACU operation may be the received row address but with its decoder select bit inverted. Based on the row address, a portion where there is a background refresh opportunity is determined. For example, the portion with the background refresh may be the portion which has a different decoder than the one specified by the row addresses' decoder select bit and also a different column decoder than the portion with the ACU operation. The refresh control circuit may determine whether or not to perform a background refresh, for example based on the refresh counter for that portion. In the example of FIG. 4, it is determined to perform a background refresh, and so a refresh address is generated by the refresh counter associated with that portion.

For the sake of explanation, reference will be made to the reference numbers of the example operation described with respect to FIG. 3 and the word lines 332-336 of the example operation described with respect to that figure. For example, the Active WL may be the word line 332, the PRAC WL may be the word line 334, and the Refresh WL may be the word line 336. Reference will also be made to the reference numbers for the row decoders and column decoders of FIG. 3. Although FIG. 4 is described with reference to FIG. 3, that is for explanation only, and the operations in FIG. 3 are not limited to the layout of FIG. 3.

At the time t0, the Activate WL 332, Refresh WL 334 and PRAC 336 are all activated responsive to the activate command and the row address associated with the activate word line. The word line 332 is activated by the row decoder 322ac, and the word lines 334 and 336 are both activated by the row decoder 322bd. Since a refresh is being performed on the Refresh WL 334, the count value associated with that row is reset. At a first time t1, the column decoder 324b writes a new value (e.g., 0) to the PRAC count to reset it, represented by the internal signal CNT. Since the PRAC count for the refreshed word line is being refreshed, the time between to and t1 may be less than a minimum row to column delay tRCD.

At a time t2, a read command RD is received. The time t2 may be at least the time tRCD after the time t0. At the time t2, the ACU operation is performed on the count value stored along the PRAC WL and a read operation is performed on the Activate WL. For example, the column decoder 324c may perform the read operation on memory cells with intersect word line 332. The column decoder 324d reads out the PRAC count from the PRAC column planes 307 which intersect the word line 334. An ACU operation is performed on the PRAC count and the updated PRAC count is written back to that same location.

In the example operation shown in FIG. 4, the read command on the active word line and the ACU operation on the PRAC word line happen more or less simultaneously at t2 because the read command RD is received at t2. However, t2 represents the earliest time at which a read command (or a write command) could be received. In another example operation, the ACU operation may still happen on the PRAC word line at t2, but a column command may be performed on the activate word line at any time between t2 and t3, when the command is received. In some example operations, more than one column command may be received between t2 and t3.

At a time t3, a pre-charge command is received. Responsive to the pre-charge command PRE, the word lines are all pre-charged. For example, the row decoder 322ac pre-charges the word line 332 and the row decoder 322bd pre-charges the word lines 334 and 336. The time between t0 and t3 may be at least a row access time tRAS. A time t4 which is after t3 the next activate command is received. The time t4 may be at least a pre-charge time tRP after the time t3. The times tRAS and tRP are defined by the specification. By performing the background refresh and ACU operation with a different row decoder than the access operation, it is possible to perform all three operations responsive to the activate command. This may allow for an extended tRAS time, which allows for column commands such as tRP. The pre-charge time tRP is shortened compared to memory devices where the ACU is performed responsive to the pre-charge command. This allows the overall access time tRC which is tRAS+tRP to remain approximately the same, while allowing for column commands without needing to extend beyond tRC. In an example implementation, tRAS may be about 36 ns and tRP may be about 16 ns.

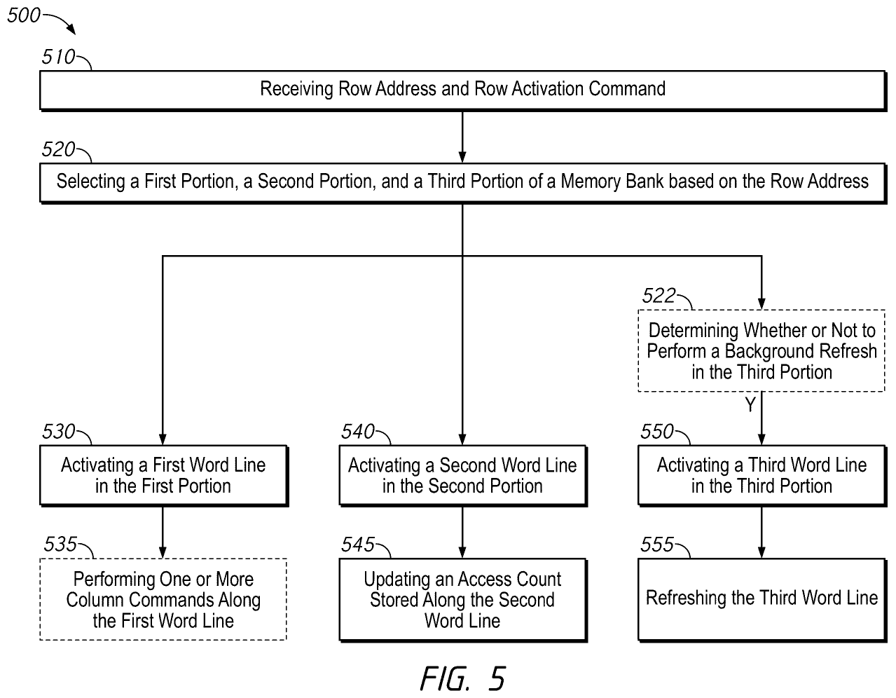

FIG. 5 is a flow chart of a method of operating a memory device according to some embodiments of the present disclosure. The method 500 may, in some embodiments, be performed by one or more of the apparatuses, systems, or combinations thereof described herein. For example, the method 500 may be performed by the memory device 100 of FIG. 1, 200 of FIG. 2, 300 of FIG. 3 or combinations thereof.

The method 500 may begin with box 510, which describes receiving a row address and a row activation command. For example, the row address and row activation command may be received along C/A terminals of a memory device. The method 500 may include decoding the row activation command with a command decoder (e.g., 106 of FIG. 1) and decoding the row address with an address decoder (e.g., 104 of FIG. 1).

Box 510 is followed by box 520, which describes selecting a first portion, a second portion, and a third portion (e.g., 332, 334, and 336 respectively of FIG. 3) of a memory bank (e.g., 118 of FIG. 1, 204 of FIG. 2, and/or 300 of FIG. 3) based on the row address. The method 500 may include selecting a first row decoder (e.g., 109ac of FIG. 1, 203ac of FIG. 2, and/or 322ac of FIG. 3) based on a row decoder select bit of the row address (e.g., the MSB) and selecting a second row decoder (e.g., 109bd of FIG. 1, 203bd of FIG. 2, and/or 322bd of FIG. 3) which is associated with an opposite of the value of the row decoder select bit. The method 500 may include selecting the first portion based on a state of the row decoder select bit and a range of the row address, selecting the second portion based on an opposite of the state of the row decoder select bit and the range of the row address, and selecting the third portion based on the opposite of the state of the row decoder select bit and another range of the row address. In some embodiments, each of the portions may be associated with a respective column decoder (e.g., 111a-d of FIG. 1 and/or 324a-d of FIG. 3). The method 500 may include selecting the second portion and the third portion such that they are associated with different column decoders.

Box 520 is followed by boxes 530 and 540 along with optional box 522. In some embodiments, box 522 may be skipped and box 520 may also be followed by box 550. Box 530 describes activating a first word line (e.g., 332 of FIG. 3) in the first portion. For example, the method may include activating the first word line with a first row decoder. Box 540 describes activating a second word line (e.g., 334 of FIG. 3) in the second portion. For example, the method may include activating the second word line with a second row decoder.

Box 522 describes determining whether or not to perform a background refresh in the third portion. For example, the method 500 may include determining whether or not to perform the background refresh based, in part, on a value of a refresh address counter (e.g., 215a-d of FIG. 2) associated with the third portion. For example, the method 500 may include comparing the value of the refresh counter to an expected number of refreshes. If it is determined to perform a background refresh, box 522 is followed by box 550 and 555. If it is not determined to perform the background refresh, then box 522 is not followed by boxes 550 and 555. Box 550 describes activating a third word line in the third portion. For example, the method may include activating the third word line with the second row decoder.

Box 530 may be followed by optional box 535 which describes performing one or more column commands along the first word line. For example, the method 500 may include receiving one or more column commands such as read or write commands, and performing the column commands along the first word line. If no column commands are received, box 535 may be skipped. Box 540 is followed by box 545 which describes updating an access count stored along the second word line. For example, an ACU circuit (e.g., 218 of FIG. 2) may increment the count value. The method may include determining if the first word line is an aggressor based on the updated count value. For example, if the updated count value crosses a threshold, the first word line may be determined to be an aggressor. The method 500 may include adding the row address to an aggressor register (e.g., 216 of FIG. 2) if the first word line is determined to be an aggressor.

If box 550 is performed, then box 550 is followed by box 555 which describes refreshing the third word line. In some embodiments, the method 500 may include resetting a count value along the third word line, for example with the ACU circuit. In some embodiments, the resetting may occur a time after the activation which is shorter than tRCD.

In some embodiments, the method 500 may include receiving a pre-charge command after performing boxes 535, 545, and 555 and pre-charging the first word line, the second word line, and the third word line responsive to the pre-charge command.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

1. An apparatus comprising:
a memory bank comprising a first portion, a second portion, a third portion, and a fourth portion;
a first row decoder coupled to the first portion and the third portion;
a second row decoder coupled to the second portion and the fourth portion;
a background refresh logic circuit,
wherein responsive to an activation command and a row address which specifies the first portion, the first row decoder activates a first word line in the first portion and the second row decoder activates a second word line in the second portion, and the background refresh logic circuit determines whether or not a background refresh operation is performed on a third word line in the fourth portion.

2. The apparatus of claim 1, further comprising:
a first column decoder coupled to the first portion;
a second column decoder coupled to the second portion;
a third column decoder coupled to the third portion; and
a fourth column decoder coupled to the fourth portion.

3. The apparatus of claim 2, wherein the first column decoder is configured to perform one or more column commands on the first word line responsive to one or more column commands.

4. The apparatus of claim 1, wherein the second row decoder is configured to activate the third word line if the background refresh logic circuit determines that a background refresh operation is performed.

5. The apparatus of claim 4, wherein the first row decoder and the second row decoder are configured to activate the first, the second, and the third word line at approximately the same time.

6. The apparatus of claim 1, further comprising a refresh control circuit comprising a first refresh counter associated with the first portion, a second refresh counter associated with the second portion, a third refresh counter associated with the third portion, and a fourth refresh counter associated with the fourth portion,
wherein the background refresh logic circuit is configured to determine whether or not to perform the background refresh operation based, in part, on a value of the third refresh counter.

7. The apparatus of claim 1, further comprising a refresh control circuit configured to update a count value along the second word line and determine if the first word line is an aggressor based on the updated count value.

8. A method comprising:
receiving a row address and a row activation command;
selecting a first portion, a second portion, and a third portion of a memory bank based on the row address;
activating a first word line in the first portion of a memory bank, a second word line in the second portion of the memory bank, and a third word line in the third portion of the memory bank responsive to the row activation command;
performing an access count update operation on an access count associated with the first word line stored along the second word line; and
performing a refresh operation on the third word line.

9. The method of claim 8, further comprising performing one or more column commands along the first word line while it is active.

10. The method of claim 8, further comprising:
receiving a pre-charge command, wherein the pre-charge command is received after the access count update operation and the refresh operation; and
pre-charging the first word line the second word line and the third word line responsive to the pre-charge command.

11. The method of claim 8, further comprising determining whether or not to perform the refresh operation on the third word line based, in part on a refresh address counter associated with the third portion.

12. The method of claim 8, further comprising:
selecting the first word line and the second word line based on the row address;
selecting a refresh counter associated with the third portion based on the row address;
generating a refresh address based on the selected refresh counter; and
selecting the third word line based on the refresh address.

13. The method of claim 8, further comprising resetting a count value along the third word line.

14. The method of claim 13, wherein the resetting is performed at a time after activating the third word line which is less than tRCD.

15. The method of claim 8, further comprising:
selecting a first row decoder based on a state of a row decoder select bit of the row address, wherein the first portion is associated with the first row decoder, and
wherein the second and the third portion are associated with a second row decoder which is associated with an opposite of the state of the row decoder select bit.

16. An apparatus comprising:
a memory bank;
a command decoder configured to receive a row activation command;
an address decoder configured to receive a row address;
a first row decoder configured to activate a first word line in the memory bank as part of an access operation responsive to the row activation command; and
a second row decoder configured activate a second word line as part of an access count update (ACU) operation, and activate a third word line as part of a refresh operation both responsive to the row activation command.

17. The apparatus of claim 16, wherein the memory bank includes a first portion, a second portion, a third portion, and a fourth portion, wherein the first portion and the third portion are coupled to the first row decoder and the second portion and the fourth portion are coupled to the second row decoder.

18. The apparatus of claim 16, further comprising an ACU circuit configured to reset a count value along the third word line, and configured to update a count value along the second word line.

19. The apparatus of claim 18, further comprising an aggressor register, wherein the row address is added to the aggressor register if the updated count value along the second word line crosses a threshold.

20. The apparatus of claim 16, wherein the command decoder is further configured to receive a pre-charge command after the activation command, and wherein the first row decoder is configured to pre-charge the first word line and the second row decoder is configured to pre-charge the second word line and the third word line responsive to the pre-charge command.
